(19) United States
(12) Patent Application Publication
(10) Pub. No.: US 2025/0262700 A1
(43) Pub. Date: Aug. 21, 2025

(54) 3D MODELLING AND ROBOTIC TOOL SYSTEM AND METHOD

(71) Applicant: Freelance Robotics Pty Ltd, Redland Bay, Queensland (AU)

(72) Inventor: William Pagnon, Redland Bay (AU)

(21) Appl. No.: 18/854,901

(22) PCT Filed: Apr. 6, 2023
(86) PCT No.: PCT/AU2023/050277

§ 371 Date: Oct. 7, 2024

(30) Foreign Application Priority Data
Apr. 6, 2022 (AU) 2022900896

(51) Int. Cl. B23Q 3/155; G06V 10/75; G06V 20/52

(52) U.S. Cl. CPC B23Q 3/1552; G06V 10/751; G06V 20/52; G06V 2201/06

(57) ABSTRACT

3D modelling and robotic tool systems and methods are provided that enable more efficient spatial processing of an object and its surroundings. The robotic tool system comprises: a scanner, configured to capture spatial data of an object and its surroundings; a processor, configured to: allocate the spatial data to cells of a cellular space; determine one or more characteristics of a cell according to data of adjacent cells; and configure a robotic tool to operate on the object at least in part according to the one or more characteristics.

### TECHNICAL FIELD

The present invention relates to 3D modelling and robotic tools. In particular, although not exclusively, the present invention relates to 3D modelling for use when interacting with physical items with robotic tools, such as robotic welding, painting, sanding, buffing, deburring, and sand blasting tools.

### BACKGROUND ART

The use of robotics is becoming increasingly popular in manufacturing, including small scale manufacturing, as the use of robotics enables consistent, high-quality work to be performed at a relatively low cost.

Examples of such use of robotics includes robotic welding, painting, sanding, buffing, deburring, and sand blasting. Almost any task performed manually may, however, be adapted to be performed by robotics.

One problem with the use of robotics in such tasks is that relatively simple tasks for humans may be relatively difficult for robotic systems. As an illustrative example, obstacle avoidance is often a relatively straightforward task for persons, but may be complicated for robotic systems.

In many cases, a point cloud is generated corresponding to the item and obstacles. A point cloud comprises many individual points, however, which may be joined to form a mesh. This mesh consists of many small faces and edges, and it is generally difficult and time consuming to analyse these small faces and edges to generate information about the item and obstacles. In short, processor intensive and time consuming edge detection algorithms are often used to detect edges of the item and obstacles to set boundaries of operation.

Another example of a relatively straightforward task for persons, but difficult for robotic systems, is path generation (e.g. calculating an optimum path from a point to a target while avoiding obstacles). While path algorithms exist, they are generally processor intensive, and must generally be recalculated if the starting point is changed.

Yet another example of a relatively straightforward task for persons, but difficult for robotic systems, is the ability to adapt to differences between an actual object and a CAD model, due to wide tolerances or otherwise.

As such, there is clearly a need for an improved 3D modelling and robotic tool methods and systems.

It will be clearly understood that, if a prior art publication is referred to herein, this reference does not constitute an admission that the publication forms part of the common general knowledge in the art in Australia or in any other country.

### SUMMARY OF INVENTION

The present invention relates to 3D modelling and robotic tool methods and systems, which may at least partially overcome at least one of the abovementioned disadvantages or provide the consumer with a useful or commercial choice.

With the foregoing in view, the present invention in one form, resides broadly in a robotic tool system comprising:
a scanner, configured to capture spatial data of an object and its surroundings;
a processor, configured to:
   allocate the spatial data to cells of a cellular space;
   determine one or more characteristics of a cell of the cellular space according to data of adjacent cells; and
   configure a robotic tool to operate on the object at least in part according to the one or more characteristics.

Advantageously, the use of the cellular space, rather than the spatial data (e.g. point cloud) directly, enables more efficient spatial processing of the object and its surroundings.

Preferably, the cellular space comprises a plurality of uniformly sized cells.

Preferably, the cellular space is three-dimensional, and each of the cells corresponds to a location in three-dimensional space.

Preferably, the cells are cubic in shape. Alternatively, the cubes are spherical in shape. Cubic cells are particularly useful for three degrees of freedom (X,Y,Z), whereas spherical cells are better suited for six degrees of freedom (X, Y, Z, Roll, Pitch, Yaw)

Preferably, the scanner is configured to generate the spatial data in the form of a point cloud. The scanner may be configured to generate the spatial data from a plurality of different angles. The scanner may be coupled to a robotic arm.

Preferably, first characteristics of the one or more of the cells are initially determined, and second characteristics of the one or more cells are determined based upon the first characteristics. An example of a first characteristic is whether the cell includes or comprises an obstacle, and an example of a second characteristic is a distance from the obstacle.

Preferably, the one or more characteristics of the cell includes a neighbourhood pattern, the neighbourhood pattern comprising a spatial pattern of a characteristic of the adjacent cells. The spatial pattern may be defined according to a binary characteristic of each of the adjacent cells. An example of a binary characteristic is whether each of the adjacent cells is occupied by an object.

The neighbourhood pattern may be represented by a code or sequence, indicating which of the adjacent cells have the binary characteristic.

The processor may be configured to compare neighbourhood patterns of adjacent cells, to determine patterns thereof. The neighbourhood patterns may be compared in a binary manner (e.g. that neighbourhood patterns are substantially the same or not).

In the case of the neighbourhood patterns defining whether each of the adjacent cells is occupied by an object, comparison of neighbourhood patterns can provide an efficient means for identifying continuous surfaces and edges. Neighbourhood patterns shared across adjacent cells may provide an efficient means for identifying continuous surfaces, and abrupt changes in neighbourhood patterns may provide an efficient means for identifying edges.

The neighbourhood pattern may be three dimensional. The neighbourhood pattern may relate to a 3×3×3 block of cells centred around the cell.

Preferably, the one or more characteristics of the cell include a score.

The score may comprise a distance score. The score may relate to a distance to a target cell. The score may relate to a distance to an obstacle.

The distance may comprise an absolute distance.

The distance may comprise a distance, measured in one or more steps. The steps may include linear steps.

The score may comprise a weighted combination of two or more scores. As an illustrative example, the score may comprise a combination of a distance to obstacles and a distance to a target. Such configuration enables both obstacle avoidance and short path to be prioritised in appropriate weights.

In some embodiments, the system may be configured to identify markings on the object, and configure a robotic tool to operate on the object at least in part according to the identified markings.

The markings may include coloured markings. The markings may comprise painted markings. Alternatively, the markings may comprise tape, or other types of markings.

The system may be configured to scan the object, detect the markings, and generate a point cloud comprising detected markings.

The point cloud comprising the detecting marking may be filtered or processed to generate a line (path). The point cloud may be filtered or processed iteratively.

The line may be generated according to average distances to other points.

The line may be smoothened, e.g. to avoid sharp turns.

In some embodiments, the system may be configured to receive a model associated with the object. The model may comprise a CAD model.

The system may be configured to align the point cloud with the model.

The system may align features (e.g. edges and/or surfaces) of the scan data with features (e.g. edges and/or surfaces) of the model.

The system may align features of the scan data to the CAD model using one or more bounding boxes.

The system may measure a deviation between the object and the model.

The model may be refined according to the deviation.

The system may determine whether the deviation is outside of a threshold.

The system may align the point cloud with the model using partial model data. Such configuration may be particularly useful when only a small portion of the part is able to be captured by the scan data (e.g. in relation to a large object).

The system may select a slice or portion of the model, and align the point cloud with the slice or portion of the model.

The system may then align the slice or portion of the model and the scan data. This may include pose refinement.

By using data points isolated to those close to the scan data, the system is capable of refining a more accurate translational (and rotational) match for the part.

The system may identify planes in the scanned point cloud data. The system may extrapolate the planes, and identify points of intersection between planes. A line (path) may then be determined based upon the intersection of planes.

The system may segment the point cloud data into blobs based on the direction of the point normal to identify the planes. An average plane through each of the blobs may be generated.

The system may provide a user interface to the user, enabling a path to be defined thereon. The user interface may visualise the object when enabling the path to be defined.

The system may scan the object after one or more tasks are performed thereon, for quality control.

The system may determine whether the points are within a predefined threshold. Localised averaging may be performed to avoid quality control failures based upon outliers in the scan data.

The system may be configured to visualise a disparity between the scanned data and a predefined model. The disparity may be shown as colour coding.

In another form, the invention resides broadly in a robotic tool method comprising:
capturing spatial data of an object and its surroundings;
allocating the spatial data to cells of a cellular space;
determining one or more characteristics of a cell of the cellular space according to data of adjacent cells; and
configuring a robotic tool to operate on the object at least in part according to the one or more characteristics.

In yet another form, the invention resides broadly in a 3D modelling system comprising:
a scanner, configured to capture spatial data of an object and its surroundings; and
a processor, configured to:
   allocate the spatial data to cells of a cellular space;
   determine one or more characteristics of a cell of the cellular space according to data of adjacent cells.

In yet another form, the invention resides broadly in a 3D modelling method comprising:
capturing spatial data of an object and its surroundings;
allocating the spatial data to cells of a cellular space; and
determining one or more characteristics of a cell of the cellular space according to data of adjacent cells.

Any of the features described herein can be combined in any combination with any one or more of the other features described herein within the scope of the invention.

The reference to any prior art in this specification is not and should not be taken as an acknowledgement or any form of suggestion that the prior art forms part of the common general knowledge.

### BRIEF DESCRIPTION OF DRAWINGS

Various embodiments of the invention will be described with reference to the following drawings, in which:

FIG. 1 illustrates a robotic tool system, according to an embodiment of the present invention.

FIG. 2 illustrates an exemplary cellular environment of the system of FIG. 1, according to an embodiment of the present invention.

FIG. 3 illustrates a 3×3×3 cell neighbourhood of the cellular environment of FIG. 2, including a cell (marked X) and its neighbouring cells.

FIG. 4 illustrates an example of a slice of the cellular environment of FIG. 2, where occupied cells are shown with shading, corresponding to a square-shaped planar surface of an item.

FIG. 5 illustrates an example of a planar surface including a cell (marked X) and its neighbouring cells, including numbering thereof.

FIG. 6 illustrates an example of a 2D cellular environment where occupied cells are shaded, neighbourhood scores are shown in the top left of each cell, and details of the neighbouring cell(s), through which the score was provided are also stored, using the nomenclature of FIG. 5.

FIG. 7 illustrates another example of a 2D cellular environment where occupied cells are shaded, target distance scores are shown in the top of each cell, and details of the neighbouring cell(s), through which the score was provided are stored, using the nomenclature of FIG. 5, in the bottom of each cell.

FIG. 8 illustrates another example of a 2D cellular environment where occupied cells are shaded, and obstacle distance scores are shown in each cell.

FIG. 9 illustrates a robotic tool method, according to an embodiment of the present invention.

Preferred features, embodiments and variations of the invention may be discerned from the following Detailed Description which provides sufficient information for those skilled in the art to perform the invention. The Detailed Description is not to be regarded as limiting the scope of the preceding Summary of the Invention in any way.

### DESCRIPTION OF EMBODIMENTS

Embodiments of the present invention are disclosed which enable 3D models of physical items and their surroundings to be created and analysed in a simple and efficient manner. These embodiments have broad application, but are particularly suited for use when interacting with physical items using robotic tools, such as robotic welding, painting, sanding, buffing, deburring, and sand blasting tools, among other applications.

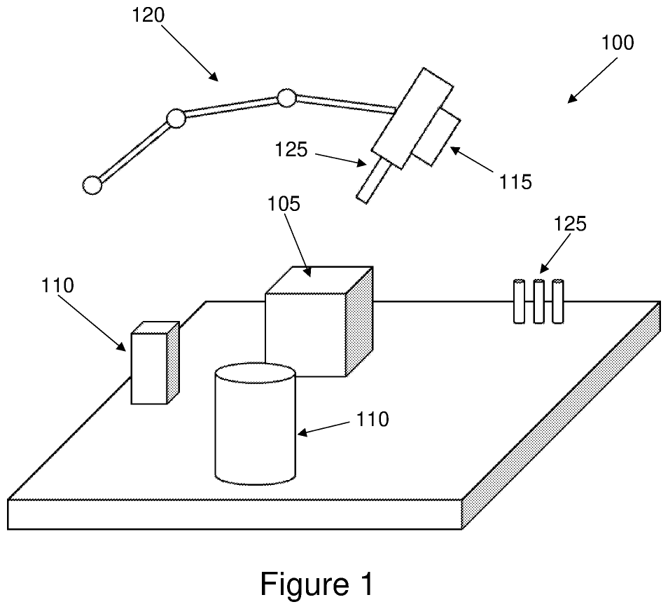

FIG. 1 illustrates a robotic tool system 100, according to an embodiment of the present invention. Advantageously, the robotic tool system 100 utilises intelligent 3D modelling to analyse items 105 and to avoid obstacles 110.

The robotic tool system 100 includes a scanner 115, coupled to a controller (not shown), the scanner 115 configured to generated a three dimensional model of the item 105 and its surroundings, including one or more obstacles 110.

The scanner 115 may be any suitable type of scanner, and in one embodiment is a laser scanner configured to generate a point cloud of the item 105 and the obstacles 110. The scanner is coupled to a robotic arm 120, and may be configured to move around the item 105 and obstacles 110 to capture data from different angles and/or to avoid occlusion.

The point cloud generated by the scanner 115 and/or controller may then be pre-processed to remove noise, to stitch point cloud data from multiple reference points, or perform any other processing or filtering of the data. In one embodiment, the scanner 115 may incorporate several scanning technologies (e.g. optical and laser scanning data), to generate the point cloud.

The controller generates a cellular environment corresponding to the item 105 and the obstacles 110 (including their surroundings). The cellular environment may be oversized to include the item 105, the obstacles 110 and space surrounding same, such that tools 125 coupled to the robotic arm 125 are able to interact with the item 105 while remaining within the cellular environment.

In particular, the cellular environment comprises a plurality of cells, each cell being cubic in shape and uniform in size. The cells thus define a coordinate system, where each cell is associated with a well-defined space, and may be associated with data.

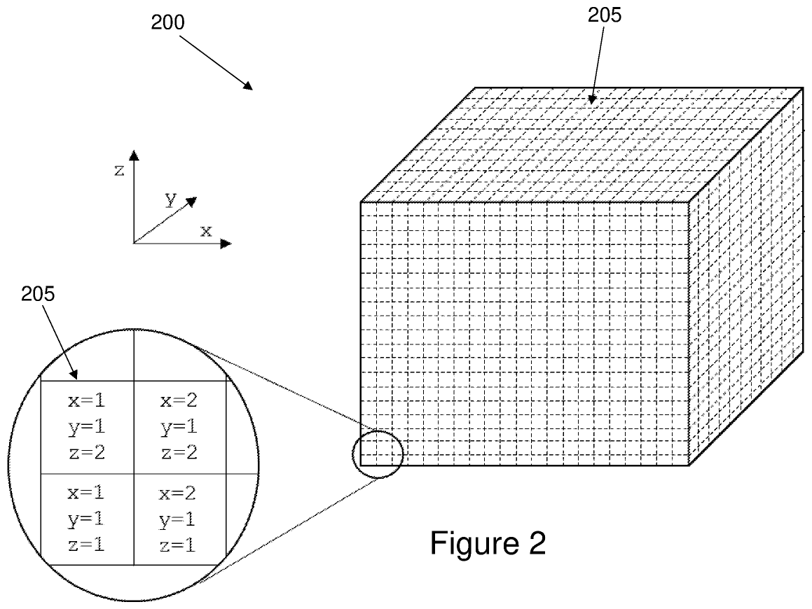

FIG. 2 illustrates an exemplary cellular environment 200, according to an embodiment of the present invention. The cellular environment 200 comprises a plurality of cells 205, each uniform in size and cubic in shape.

Each cell 205 is identifiable by a coordinate (x,y,z) defining the relative position of each cell 205 in the cellular environment 200. Each axis of the coordinate system (x, y and z) is perpendicular to a face of each of the cells 205. Furthermore, each cell may be associated with rotational axis, such as roll, pitch and yaw, to enable 6 degrees of freedom to be applied to a tool.

In the example cellular environment 200, the leftmost, lowermost and forwardmost cell 205 is the origin cell (x=1, y=1, and z=1), but the skilled person will readily appreciate that any origin or reference point may be used.

In alternative embodiments, the cellular environment is defined by cells that are uniform in size, but of another shape, e.g. spherical. Such configuration is particularly useful when 6 or more degrees of freedom are associated with each cell, as it enables faces of each cell to be associated with a degree of freedom.

The skilled addressee will readily appreciate that the term spherical does not necessarily strictly mean a spherical shape, but in the context of the cellular environment may represent a sphere in shape. As an illustrative example, the spherical cells may actually be dodecahedron in shape.

The point cloud created by the scanner is then overlaid on the cellular environment 200, and cells are categorised according to the point cloud. In particular, each point of the point cloud is allocated to a cell 205, and cells corresponding to points of the point cloud are categorised as “occupied”. Any categorisation may, however, be used, as outlined below. In some embodiments, categorisation of cells may include whether a cell is empty or filled, and in such case whether it is filled with an item or an obstacle, details of material type/texture, cell welding parameters, process to be performed on the cell, or any suitable data. Furthermore, such categorisation may be provided in relation to clusters of cells.

Similarly, cells may be associated with an intensity, much like a magnetic field around items, but relation to whether a cell is solid or not rather than magnetic. For instance, a cell filled completely with a solid will be an intensity field of 1, with softer matter, an intensity field of less than 1 (e.g. 0.9) may be used. Furthermore, such intensity data may be provided to illustrate how far each cell is from a solid.

The resolution of the cellular environment 200 may correspond to the dimensional size of the scanned data such that adjacent points in the point cloud form a continuous arrangement of cells 205 in the cellular environment 200. Furthermore, the point cloud may be filtered, re-sampled, or otherwise processed when being overlaid to the cellular environment 200.

Once the cells 205 are initially categorised, they may be processed, and scores may be generated for each cell according to one or more characteristics thereof.

In one embodiment, a neighbourhood pattern is determined for each cell 205 according to characteristics of an immediate neighbourhood of the cell 205. The neighbourhood pattern may relate to a binary characteristic, such as whether the neighbouring cells are occupied or not, or any other suitable characteristic of the cells 205.

Each cell 205, with the exception of cells on the outer edges of the cellular environment 200, includes 26 neighbours (i.e. a 3×3×3 cube centred around the cell 205). A pattern may be calculated for each cell based upon data for each of these 26 surrounding cells, much like a spatial filter (also called a kernel or mask) in image processing.

The 26 neighbours for a cell having coordinates X,Y,Z are defined by the following coordinates: (X−1,Y−1,Z+1), (X,Y−1,Z+1), (X+1,Y−1,Z+1), (X−1,Y−1,Z), (X,Y−1,Z), (X+1,Y−1,Z), (X−1,Y−1,Z−1), (X,Y−1,Z−1), (X+1,Y−1,Z−1), (X−1,Y,Z+1), (X,Y,Z+1), (X+1,Y,Z+1), (X−1,Y, Z+1), (X−1,Y,Z−1), (X,Y,Z−1), (X+1,Y,Z−1), (X−1,Y+1,Z+1), (X,Y+1,Z+1), (X+1,Y+1,Z+1), (X−1,Y+1,Z), (X,Y+1,Z), (X+1,Y+1,Z), (X−1,Y+1,Z−1), (X,Y+1,Z−1) and (X+1,Y+1,Z−1). These cells are identified by numbers 1-26 respectively.

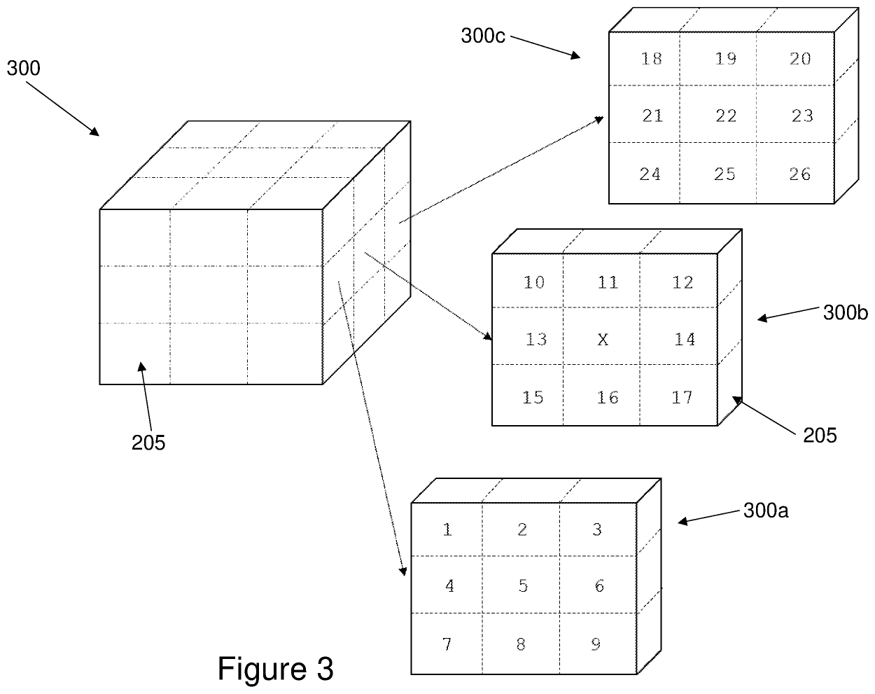

FIG. 3 illustrates a 3×3×3 cell neighbourhood 300, including a cell 205 (marked X) and its neighbouring cells, including numbering thereof.

The cell neighbourhood 300 is shown exploded into three vertical slices 300a, 300b, 300c, for the sake of clarity.

The numbering enables each of the cells to be unambiguously addressed, and a code or sequence to be generated. The skilled addressee will readily appreciate that the numbering is merely a label, and any numbering of the neighbouring cells, or any other way of identifying the cells, may be used.

In one embodiment, the neighbourhood pattern may be defined according to a binary characteristic of each cell, such as an occupancy of each neighbouring cell. In particular, each cell may be associated with a pattern corresponding to the surrounding cells that are occupied.

As an illustrative example, if the neighbouring cells with Y=y are occupied, the neighbouring pattern would be: 10, 11, 12, 13, 14, 15, 16, 17 (i.e. all cells in slice 300b), using the nomenclature of FIG. 3. This would generally correspond to a vertical surface perpendicular to the y-axis.

Importantly, neighbouring cells 205 which share a common neighbouring pattern (or substantially identical neighbouring pattern) generally form part of a common surface. This not only applies to surfaces perpendicular to an axis of the coordinate system, but any suitable surface.

Similarly, neighbouring cells which have substantially different neighbouring patterns generally form part of an edge or irregular portion of the surface.

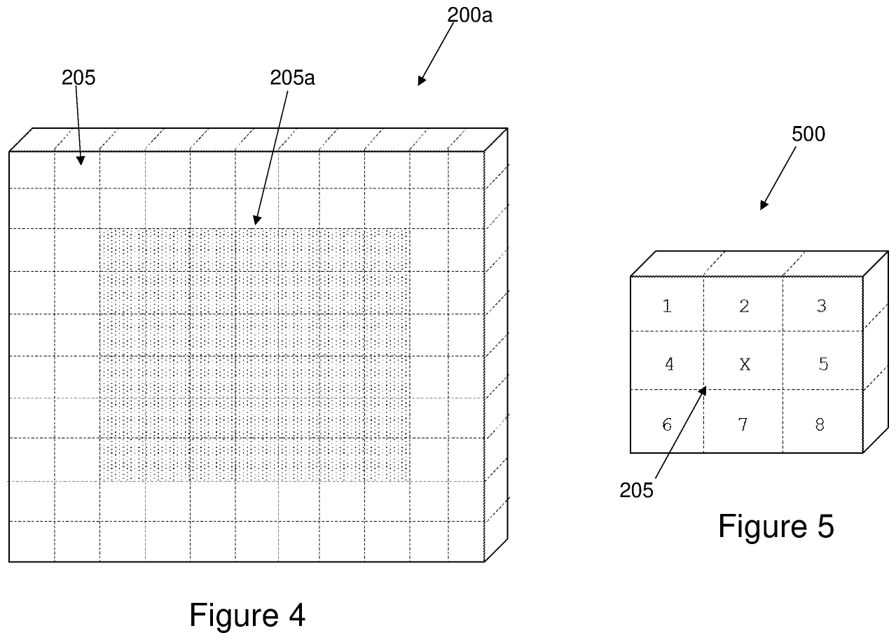

FIG. 4 illustrates an example of a slice 200a of the cellular environment 200 where occupied cells 205a are shown with shading, corresponding to a square-shaped planar surface of the item 105.

The central occupied cells 205a all have the same neighbouring pattern (i.e. 10, 11, 12, 13, 14, 15, 16, 17) whereas the uppermost occupied cells 205a have a different pattern (i.e. 13, 14, 15, 16, 17). Similarly, the bottommost occupied cells 205a have a different pattern (i.e. 10, 11, 12, 13, 14) as do the left-and right-most occupied cells 205a.

As a result, comparing the neighbouring pattern of the occupied cells 205a provides a simple way of identifying surfaces, particularly uniform surfaces, and edges.

While the examples illustrated comprise vertical surfaces for the sake of clarity, the skilled addressee will readily appreciate that the surfaces may take any form. As an illustrative example, a rear-tilting surface at an angle of approximately 45 degrees may have a neighbouring pattern of (7, 8, 9, 13, 14, 18, 19, 20).

Any suitable measure may be used to compare neighbouring patterns, including identical matches, matching neighbourhood patterns above a particular threshold (e.g. above 75%), or more intelligent comparisons of similarity (e.g. where it is taking into account that positions 10 and 18 are adjacent to each other, and thus much closer to each other than 15 and 18).

While the above examples are shown with a neighbourhood size of 3×3×3 (26 neighbours plus the cell), in other embodiments different neighbourhood sizes may be used (e.g. 5×5×5), and even non-cubic neighbourhood shapes.

Furthermore, the system 100 is particularly useful in obstacle avoidance and path generation, particularly when the robotic arm 120 and tools 125 interact with the item 105. In such case, a target (end) point may be identified, and the system 100 generate a path for the robotic arm 120 from its current position to the end point.

To achieve this, or for other types of calculations, in some embodiments, one or more neighbourhood scores are calculated according to characteristics of the neighbouring cells, including in relation to the target cell.

An example of one such score is a neighbourhood level score, which relates to a distance a cell has from the target according in linear steps.

Neighbourhood scoring is performed by starting at the target cell, and setting all non-obstacle cells neighbouring the target cell with the value 1, as it is possible to move in a linear fashion from each of these neighbouring cells to the target cell in one step.

This score is repeated in cells extending outwardly from the target cell linearly until an obstacle is reached (or the edge of the cellular environment 200 is reached).

Once all cells are scored in this manner, any unscored neighbours of a scored cell are scored with the value ‘2’, which is repeated in cells extending outwardly linearly until an obstacle is reached (or the edge of the cellular environment 200 is reached).

The process is repeated iteratively, increasing the score by 1 each time, until all cells are scored.

In addition to storing the score in association with each cell, details of the neighbouring cell(s) through which the score was provided are also stored. This enables easy identification of not only how many linear movements each cell is from the target, but also the direction in which to start those movements.

An example of a neighbourhood score is described below in a two-dimensional environment, for the sake of clarity. The skilled addressee will readily appreciate that the teachings may be equally applied to a three-dimensional environment.

Each cell 205 on a planar surface has 8 neighbours (i.e. a 3×3 square centred around the cell 205), and these cells are identified by numbers 1-8 respectively.

FIG. 5 illustrates an example of a planar surface 500 including a cell 205 (marked X) and its neighbouring cells, including numbering thereof. The numbering enables each of the neighbouring cells to be unambiguously addressed relative to the cell 205 and an associated code to be generated.

Like above, the skilled addressee will readily appreciate that the numbering is merely a label, and any numbering of the neighbouring cells may be used.

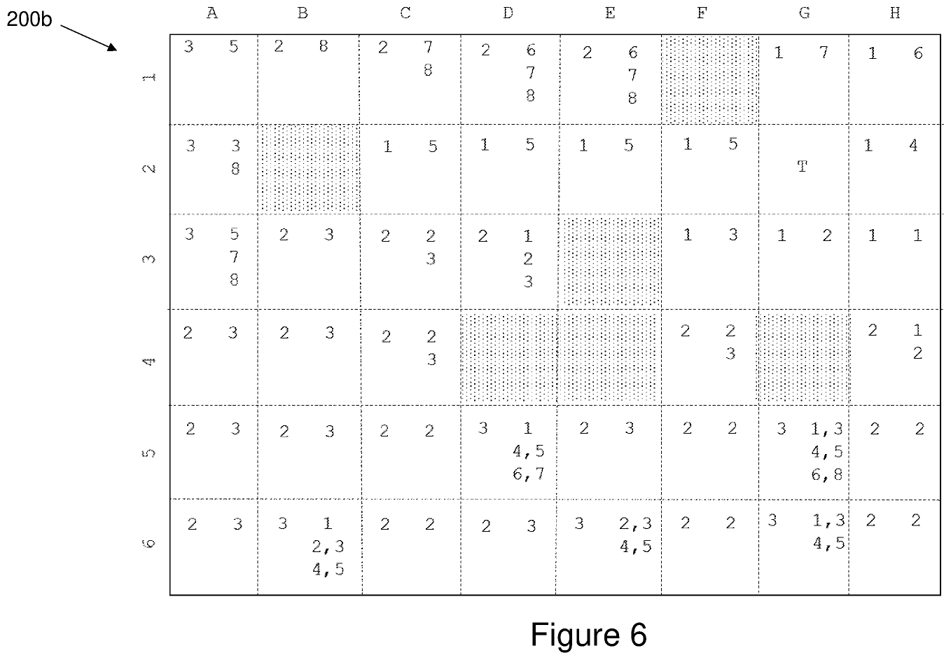

FIG. 6 illustrates an example of a 2D cellular environment 200b where occupied cells 205a are shaded, neighbourhood scores are shown in the top left of each cell, and details of the neighbouring cell(s), through which the score was provided are also stored, using the nomenclature of FIG. 5.

Initially, cells G1, H1, F2, H2, F3, G3 and H3 are given score 1 as they are in direct proximity to the target (T), and from these cells movement to the target can be made in a single linear movement. Cell F2 gets its score from the target, which is located at position 5 for F2.

Cell E2 (neighbour number 4 of cell F2) also gets score 1, as does cell D2 and C2 (all being sequentially neighbour number 4 from the target).

Once all cells eligible to have score 1 are allocated, level 2 scoring is started. For example, cell D3 gets its score (score 2) from cells C2, D2 and E2 (which are at positions 1, 2, and 3 for D3).

The process is then repeated for the remaining cells until all non-occupied cells are allocated a score.

In use, the scores and details of the neighbouring cell(s) through which the score was provided, can be used to provide an efficient path from any cell to the target T with as few linear steps as possible.

As an illustrative example, cell B3 has a score of 2, indicating that the target may be reached with two linear movements, and has details of neighbouring cell ‘3’ (top right). As such, the first linear movement is diagonally upwards until the score changes, which happens at cell C2. Cell C2 has a score of 1, and details of neighbouring cell ‘5’ (right), indicating that the target can be reached in a single linear movement to the right.

Another example of a score is a target distance score, which relates to a distance a cell has from the target in number of cells (i.e. an absolute distance).

Target distance scoring is performed by starting at the target cell 205, and setting all non-obstacle cells directly above, below or beside the target cell 205 with the value 1, and any cells diagonally adjacent to the target cell with the value \sqrt{2} (or an approximation thereof).

This scoring is repeated in neighbouring cells, by scoring each non-obstacle cells directly above, below or beside the cell 205 with the value K+1, where K is the score of the cell 205, and any cells diagonally adjacent to the target cell with the value K+\sqrt{2} (or an approximation thereof).

If a cell receives multiple different scores from different neighbours, the smallest score is recorded (i.e. the smallest score overrides the larger score).

Once all cells are scored in this manner, the process is repeated for neighbouring cells of those cells, and so on, until all cells are scored.

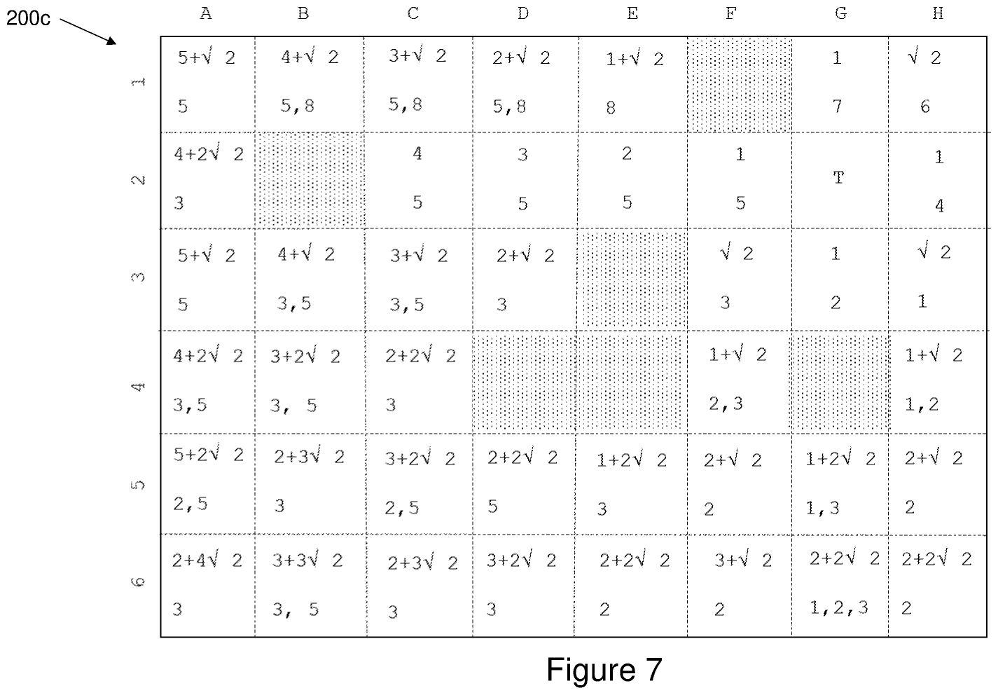

FIG. 7 illustrates an example of a 2D cellular environment 200c where occupied cells 205a are shaded, target distance scores are shown in the top of each cell, and details of the neighbouring cell(s), through which the score was provided are stored, using the nomenclature of FIG. 5, in the bottom of each cell.

Initially, cells G1, F2, H2, and G3 are given score 1 as they are directly above, below or beside the target, and cells H1, F3 and H3 are given score \sqrt{2} as they are located diagonally with reference to the target. Each cell may be given a score for each orientation associated with the cell. This is then repeated on neighbouring cells to those just scored, and so on until all eligible cells have been scored.

For example, cell E1 is scored 1+\sqrt{2} being the score of F2 (i.e. 1) plus the diagonal distance from F2 (i.e. \sqrt{2}). F2 is in position 8 for cell E1, and as such, details of position 8 are stored in relation to E1.

In use, the scores and details of the neighbouring cell(s) through which the score was provided can be used to provide the shortest path from any cell to the target.

As an illustrative example, cell E1 has a score of 1+\sqrt{2}, indicating that the target is 1+\sqrt{2} steps away, and has details of neighbouring cell ‘8’ (bottom right). As such, the first movement is diagonally downwards (i.e. to cell F2). Cell F2 has a score of 1, and details of neighbouring cell ‘5’ (right), indicating that the target can be reached by moving a single step to the right.

Yet another example of a score is an obstacle distance score, which relates to a distance a cell has from an obstacle in number of cells (i.e. an absolute distance).

Obstacle distance scoring is performed by starting at obstacles, and setting all non-obstacle cells immediately adjacent to the obstacle with the value 1. The process is then repeated with all non-scored neighbours, increasing the score by 1 each time.

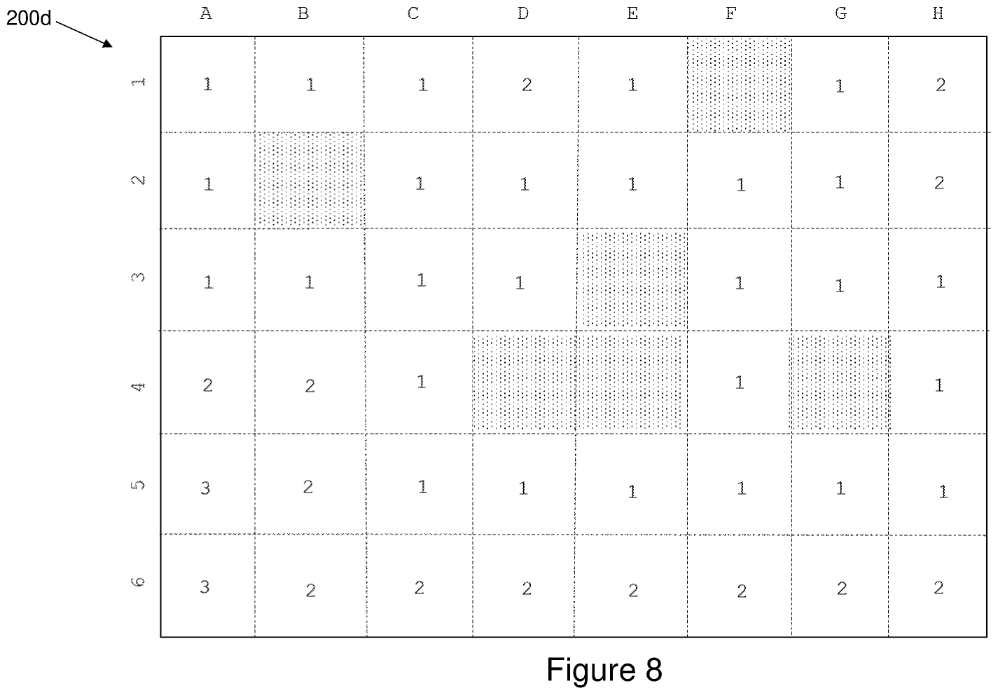

FIG. 8 illustrates an example of a 2D cellular environment 200d where occupied cells 205a are shaded, and obstacle distance scores are shown in each cell.

Cell B4, for example, is allocated value 2, indicating it is two steps away from an obstacle. It is equal distance from the obstacle at B2 and D4.

As the path data outlined above is generated for each cell, there is no need to recalculate data should the starting point change, which adds flexibility to the system, particularly if multiple tasks are being performed.

In some embodiments, multiple scores may be calculated for each of a plurality of cells, and the scores combined. As an illustrative example, if a path that is short, but also maintains a distance from obstacles is desired, a combination of target distance scoring and obstacle distance scoring may be used.

In some embodiments, a combination of the above scores is simultaneously generated. As an illustrative example, an obstacle distance score may be first calculated, and considered when calculating the neighbourhood score. In one example, the neighbourhood score may be calculated with the additional requirement that the cells having a pre-defined distance (e.g. 1 or 2) or less to an obstacle are not considered.

In one embodiment, cells are categorised according to one or more scores, outlined above, neighbourhood patterns, or a derivative thereof.

In some embodiments, each cell may be categorised in two or more ways.

The categorisations and/or scores may be used when interacting with the item 105. As an illustrative example, the tool 125 may comprise a welding tool, and the scores and categorisation used to determine a path from the location of the tool 125 to the item 105, and along a welding path of the item 105. This may include considering regions of interest for welding and/or other constraints.

A plurality of different tools 125 may be provided in an interchangeable manner, enabling an appropriate tool to be chosen. In one embodiment, a welding tool may be initially used, followed by one or more of sanding, deburring, buffing, and painting.

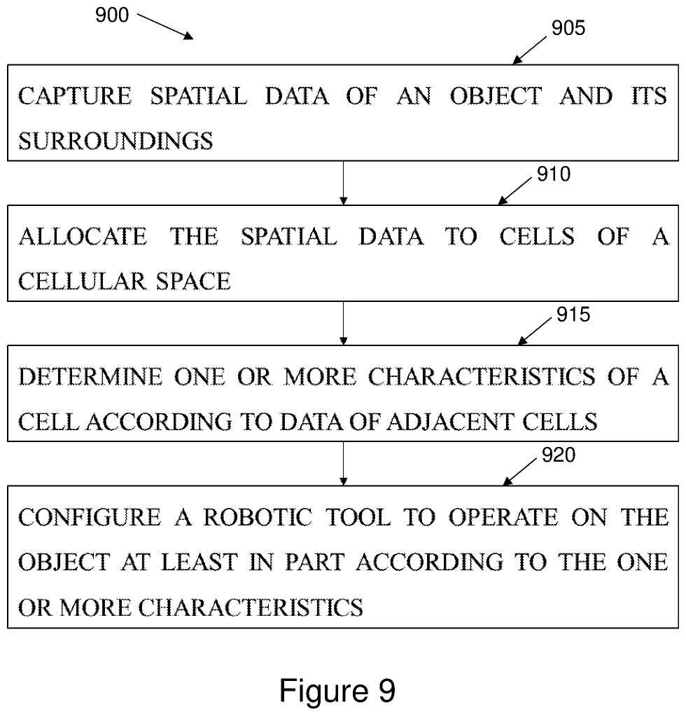

FIG. 9 illustrates a robotic tool method 900, according to an embodiment of the present invention. The method 900 may be similar or identical to the method use by the system 100.

At step 905, spatial data of an object and its surroundings is captured, e.g. using a laser scanner. The spatial data may comprise a point cloud.

At step 910, the spatial data is allocated to cells of a cellular space. The cellular space may comprise a plurality of cubic cells of equal size, corresponding to location in three dimensional space.

At step 915, one or more characteristics of a cell are determined according to data of adjacent cells. The characteristics may include whether the cell is occupied by the item, whether the cell comprises an obstacle, or a neighbourhood pattern of the cell, for example.

At step 920, a robotic tool, such as a robotic welder, is configured to operate on the object at least in part according to the one or more characteristics. This could include avoiding obstacles, determining an efficient path, or any other characteristic.

In some embodiments, markings may be placed on the object to assist the system in identifying paths thereon. An example of such marking is paint.

In use, a user may deliberately mark the item, e.g. with coloured paint, to an approximate path, e.g. for welding. As such, the paint is a form of input to the system to define the path to be welded, or otherwise worked on.

The system may scan the item to create a point cloud of the item, detect the marking (e.g. paint), and identify points in the point cloud associated with the markings.

As a result, in some embodiments, an item (e.g. a part) may be scanned to generate a mesh or point cloud with markings in a single scan. The system is then able to run a welding (or other) simulation, followed by a cold run of the welding (or other) tool. Finally, a hot run on the part may be performed. This process may take a very small time (<10 minutes for a small part), which is significantly faster than prior art systems. Furthermore, once this is performed once, the scanned part can be used to generate further item, scan jigs and even adjust for obstacles.

The system may then filter or process these points to generate a line (path). Such configuration is necessary, as the paint will be generally much thicker than the resolution of the scanner, and thus many points together will corresponding to the marking.

The line may be generated according to average distances to other points.

The point cloud may be filtered or processed iteratively. As an illustrative example, the process of choosing a path from the marked points may be performed iteratively. For example, the process may include averaging points within a certain radius, and using that point as a new starting point to find the centre of a line.

The system may also be configured to smoothen the line, e.g. by penalising sharp turns.

The system may be configured to receive a model associated with the object. The model may comprise a CAD model. As will be readily appreciated, the object may not conform exactly to the object due to wide tolerances or otherwise.

The system may align the point cloud with the model. This may be achieved by aligning features (e.g. edges and/or surfaces) of the scan data with features (edges and/or surfaces) of the model.

The system may align features of the scan data to the CAD model using one or more bounding boxes. The bounding box may be used to search for corresponding points in the point cloud.

The system may measure a deviation between the object and the model and refine the model according to the deviation. The refined model advantageously better matches the object than the original model.

The system may determine whether the deviation is outside of a threshold and issue an alert or warning to the user.

In many cases, only a portion of the object is described by the scanned point cloud data, e.g. in relation to large objects. In such case, matching the point cloud to the model can be problematic with existing methods, particularly if much of the model is not relevant to the partial point cloud data.

In such case, matching processed may be initially performed to provide a rough location for the object with reference to the scan data.

A comparison is then performed between the scan data and the model, and points from the model are selected based on their distance to the scan data.

This essentially creates a new partial model of the object which corresponds to the point cloud only (and not areas of the model not seen in the point cloud) to simplify and improve alignment. The new partial model may comprise a “slice” of the model.

Matching (alignment) is then performed with reference to the new partial model and scan data, which is simpler, as irrelevant points from the model are removed, meaning less data needs to be processed, and more accurate, as the impact from potentially irrelevant points on the model is removed.

It is further desirable for the system to assist in generating paths, e.g. for welding, rather than having these input manually by users.

Various types of edge detection may be used to assist in generating paths, particularly in relation to welding.

The system may identify planes in the scanned point cloud data, extrapolate the planes, and identify points of intersection between planes. A line (path) may then be determined based upon the intersection of planes. Such lines are particularly useful when welding objects at their edges.

In particular, the system may segment the point cloud data into blobs based on the direction of the point normal to identify the planes. An average plane through each of the blobs may be generated.

For each set of planes, the points at which the planes intersect may be identified and filtered to create a line (path).

Such feature may reduce the amount of human interaction needed to set up paths for the system.

In some embodiments, the generation of such lines (which correspond to edges) are used to align the object to the model. In such case, the line may be seen as an edge, and aligned to an edge of the model.

The system may provide a user interface to the user, enabling a path to be defined thereon. The user interface may visualise the object when enabling the path to be defined.

As an illustrative example, a visualisation of the object may be provided, on which the user may be able to defined paths by clicking on points of the object.

Furthermore, the teachings discloses above may be used to generate or define jigs for welding (or otherwise working on) items in a repeatable matter. For example, a jig and an item may be simultaneously scanned, enabling recreation of the jig and recreation of the item using the jig.

In addition to assisting in working on objects, the system may scan the object after one or more tasks are performed thereon, for quality control.

The system may determine whether the points are within a predefined threshold. Localised averaging may be performed to avoid quality control failures based upon outliers in the scan data.

The system may be configured to visualise a disparity between the scanned data and a predefined model. The disparity may be shown as colour coding, like a heat map. This provides a clear, human readable, visualisation for deviations in the object.

In some embodiments, metrics are provided to allow a robot to automatically perform quality control of its work. For example, along with the CAD model, an object may be given a set tolerance for how accurate the manufactured item must be with respect to the CAD (ideal) model. Depending on this tolerance, the final object may pass or fail a final inspection.

Furthermore, robotic welders and the like operate at a high level of precision and, without a method to compensate, and generally require that any part presented for them to work on is also at a high level of precision.

For parts with wide tolerances, it is beneficial to morph and align the model to the point cloud, to essentially generate a new model corresponding to the object using the above methods, or others.

Such matching and morphing may be performed on surfaces of the object individually. In such case, for each point on the surface of the model, corresponding points are identified in the point cloud, and moved. The new deviated data points are then used instead of the model.

Advantageously, embodiments of the invention enable 3D models of physical items and their surroundings to be created and analysed in a simple and efficient manner, e.g. to avoid obstacles. These embodiments have broad application, but are particularly suited for use when interacting with physical items using robotic tools, such as robotic welding, painting, sanding, buffing, deburring, and sand blasting tools. As the path data is generated for each cell, there is no need to recalculate data should the starting point change, which adds flexibility to the system, particularly if multiple tasks are being performed.

In the present specification and claims (if any), the word ‘comprising’ and its derivatives including ‘comprises’ and ‘comprise’ include each of the stated integers but does not exclude the inclusion of one or more further integers.

Reference throughout this specification to ‘one embodiment’ or ‘an embodiment’ means that a particular feature, structure, or characteristic described in connection with the embodiment is included in at least one embodiment of the present invention. Thus, the appearance of the phrases ‘in one embodiment’ or ‘in an embodiment’ in various places throughout this specification are not necessarily all referring to the same embodiment. Furthermore, the particular features, structures, or characteristics may be combined in any suitable manner in one or more combinations.

In compliance with the statute, the invention has been described in language more or less specific to structural or methodical features. It is to be understood that the invention is not limited to specific features shown or described since the means herein described comprises preferred forms of putting the invention into effect. The invention is, therefore, claimed in any of its forms or modifications within the proper scope of the appended claims (if any) appropriately interpreted by those skilled in the art.

1. A robotic tool system comprising:
a scanner, configured to capture spatial data in the form of a point cloud of an object and its surroundings;
a processor, configured to:
allocate the spatial data to cells of a cellular space;
determine one or more characteristics of a cell according to data of adjacent cells; and
configure a robotic tool to operate on the object at least in part according to the one or more characteristics.

2. The robotic tool system of claim 1, wherein the cellular space comprises a plurality of uniformly sized cells.

3. The robotic tool system of claim 2, wherein the cellular space is three-dimensional, and each of the cells corresponds to a location, and optionally an orientation, in three-dimensional space, and wherein the cells are cubic or spherical in shape.

4.-5. (canceled)

6. The robotic tool system of claim 1, wherein first characteristics of the one or more of the cells are initially determined, and second characteristics of the one or more cells are determined based upon the first characteristics.

7. The robotic tool system of claim 6, wherein the one or more characteristics of the cell includes a neighbourhood pattern, the neighbourhood pattern comprising a spatial pattern of a characteristic of the adjacent cells.

8. The robotic tool system of claim 7, wherein the neighbourhood pattern may be represented by a code or sequence, indicating which of the adjacent cells have a characteristic.

9. The robotic tool system of claim 7, wherein the processor is configured to compare neighbourhood patterns of adjacent cells, to determine patterns thereof.

10. The robotic tool system of claim 7, wherein the neighbourhood pattern is three dimensional.

11. The robotic tool system of claim 1, wherein the one or more characteristics of the cell include a score, the score comprising a weighted combination of two or more scores relating to different characteristics.

12. (canceled)

13. The robotic tool system of claim 1, further configured to identify markings on the object, and configure a robotic tool to operate on the object at least in part according to the identified markings.

14. (canceled)

15. The robotic tool system of claim 13, configured to scan the object, detect the markings, and generate a point cloud comprising detected markings, wherein the point cloud comprising the detecting marking is filtered or processed to generate a line (path).

16. The robotic tool system of claim 1, further configured to receive a model associated with the object, and to align the spatial data with the model.

17. The robotic tool system of claim 16, configured to align features (e.g. edges and/or surfaces) of the spatial data with features (e.g. edges and/or surfaces) of the model.

18. The robotic tool system of claim 16, configured to measure a deviation between the object and the model, and refine the model according to the deviation.

19. The robotic tool system of claim 16, configured align the spatial data with the model using partial model data in the form of a slice or portion of the model.

20. The robotic tool system of claim 1, further configured to identify planes in the scanned spatial data, extrapolate the planes, and identify points of intersection between the extrapolated planes to generated lines (paths) based upon the intersection of planes.

21. The robotic tool system of claim 1, further configured to scan the object after one or more tasks are performed thereon, and compare same with a predefined model, and output a disparity between the scanned data and a predefined model.

22. The robotic tool system of claim 21, further configured to visualise a disparity between the scanned data and a predefined model.

23. A robotic tool method comprising:
capturing spatial data of an object and its surroundings, the spatial data in the form of a point cloud; allocating the spatial data to cells of a cellular space;
determining one or more characteristics of a cell according to data of adjacent cells; and
configuring a robotic tool to operate on the object at least in part according to the one or more characteristics.

24. (canceled)

25. A 3D modelling method comprising:
capturing spatial data of an object and its surroundings, the spatial data in the form of a point cloud;
allocating the spatial data to cells of a cellular space; and
determining one or more characteristics of a cell according to data of adjacent cells.
